(19) United States
(12) Patent Application Publication
(10) Pub. No.: US 2010/0139741 A1
(43) Pub. Date: Jun. 10, 2010

(54) Frame-Integrated Pivot Bearing For Solar Collector Assembly

(76) Inventor: Brian S. WARES, San Francisco, CA (US)

Correspondence Address: Okamoto & Benedicto LLP, P.O. Box 641330, San Jose, CA, 95164-1330, US

(21) Appl. No.: 12/577,414

(22) Filed: Oct. 12, 2009

(51) Int. Cl. H01L 31/048; H01L 21/50

(52) U.S. Cl. 136/251; 438/66; 257/E21.499

(57) ABSTRACT

One embodiment relates to a photovoltaic array assembly which includes a plurality of photovoltaic modules and a frame surrounding and supporting each of the photovoltaic modules in an array. A plurality of pivot bearings are advantageously integrated into the frame along a single axis. Another embodiment relates to a method of manufacturing a photovoltaic array assembly. The method includes manufacturing a frame to surround and support a plurality of photovoltaic modules in an array. The method further includes integrating a plurality of pivot bearings into the frame and inserting the plurality of photovoltaic modules into the frame. Other embodiments, features and aspects are also disclosed.

### STATEMENT REGARDING FEDERALLY SPONSORED RESEARCH OR DEVELOPMENT

This invention was made with Government support under Contract No. DEFC36-07GO17043 awarded by the United States Department of Energy. The Government has certain rights in this invention.

### BACKGROUND OF THE INVENTION

1. Field of the Invention

The present disclosure relates to solar collector assemblies.

2. Description of the Background Art

Photovoltaic cells, also known as “solar cells,” are devices for converting solar radiation to electrical energy. Photovoltaic cells are typically arranged into an array and packaged as a photovoltaic (PV) module, also known as a “solar module.”

Photovoltaic modules may also be installed in solar collector arrays with capacities from a few kilowatts to hundreds of kilowatts, or more. Solar collector arrays are typically installed where there is an area with exposure to the sun for significant portions of the day. These arrays may be configured to track a diurnal motion of the sun to increase an amount of solar energy that is collected.

### SUMMARY

One embodiment relates to a photovoltaic array assembly which includes a plurality of photovoltaic modules and a frame surrounding and supporting each of the photovoltaic modules in an array. A plurality of pivot bearings are advantageously integrated into the frame along a single axis.

Another embodiment relates to a method of manufacturing a photovoltaic array assembly. The method includes manufacturing a frame to surround and support a plurality of photovoltaic modules in an array. The method further includes integrating a plurality of pivot bearings into the frame and inserting the plurality of photovoltaic modules into the frame.

Other embodiments, aspects and features are also disclosed.

### BRIEF DESCRIPTION OF THE DRAWINGS

FIG. 1 depicts a conventional solar collector arrangement with an array of photovoltaic modules supported by a structure having a torsion tube.

FIG. 2 depicts a solar collector arrangement with an array of photovoltaic modules supported by a structure including a frame with integrated pivot bearings and pivot attachments in accordance with an embodiment of the invention.

FIG. 3 depicts an integrated pivot bearing in a frame in accordance with an embodiment of the invention.

FIG. 4 depicts a closer view of the integrated pivot bearing in accordance with an embodiment of the invention.

FIG. 5 is an exploded view drawing showing separated parts of a frame-integrated pivot bearing in accordance with an embodiment of the invention.

FIG. 6 is a cross-sectional exploded view drawing showing separated parts of a frame-integrated pivot bearing in accordance with an embodiment of the invention.

FIG. 7 is a cross-sectional view drawing showing an assembled frame-integrated pivot bearing in accordance with an embodiment of the invention.

FIG. 8 is a perspective view of an attachment device between a pier and an inner frame member in accordance with an embodiment of the invention.

### DETAILED DESCRIPTION

In the present disclosure, numerous specific details are provided, such as examples of apparatus, process parameters, materials, process steps, and structures, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

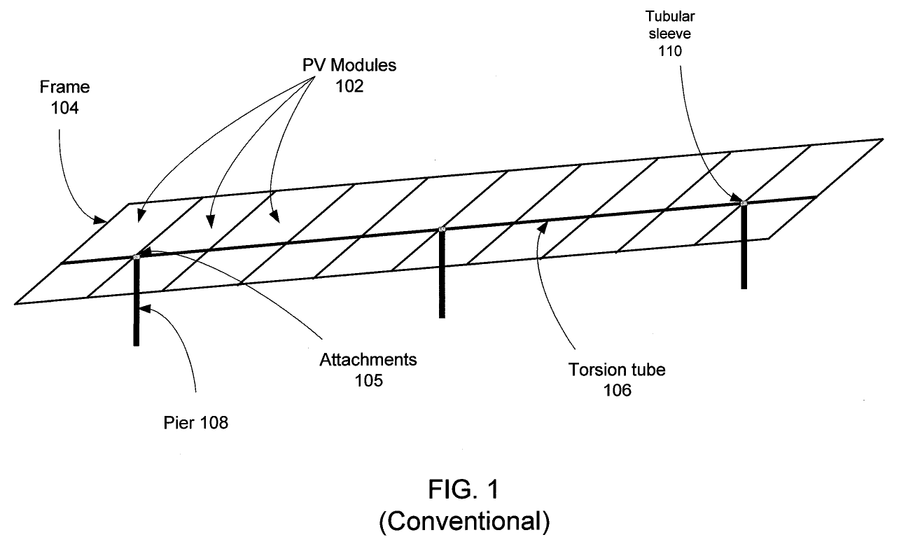

FIG. 1 depicts a conventional solar collector arrangement with an array of photovoltaic modules 102 supported by a structure having a torsion tube 106. In this illustration, ten PV modules 102 are shown in a linear array. As seen the linear array of PV modules 102 are configured to be held within a frame 104. The frame 104 is configured with attachments 105 to connect to a common torsion tube 106. The attachments 105 may be cap weldments with transverse tubular sleeves, and the cap weldments may be attached to the top of support piers 108.

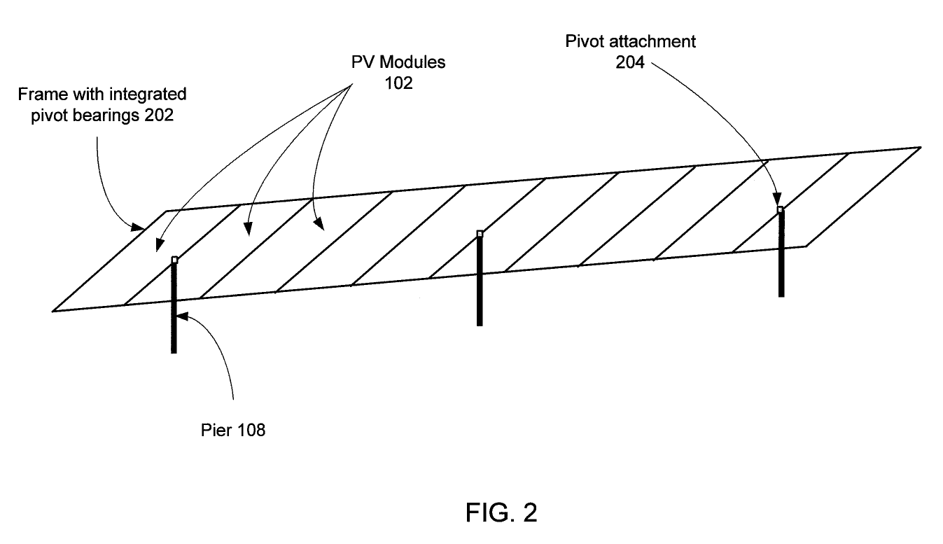

FIG. 2 depicts a solar collector arrangement with an array of photovoltaic modules 108 supported by a structure including a frame with integrated pivot bearings 202 and pivot attachments 204 in accordance with an embodiment of the invention. The pivot attachments 204 are configured to attach to the integrated pivot bearings of the frame 202. In accordance with an embodiment of the invention, the support structure in this arrangement does not require a torsion tube.

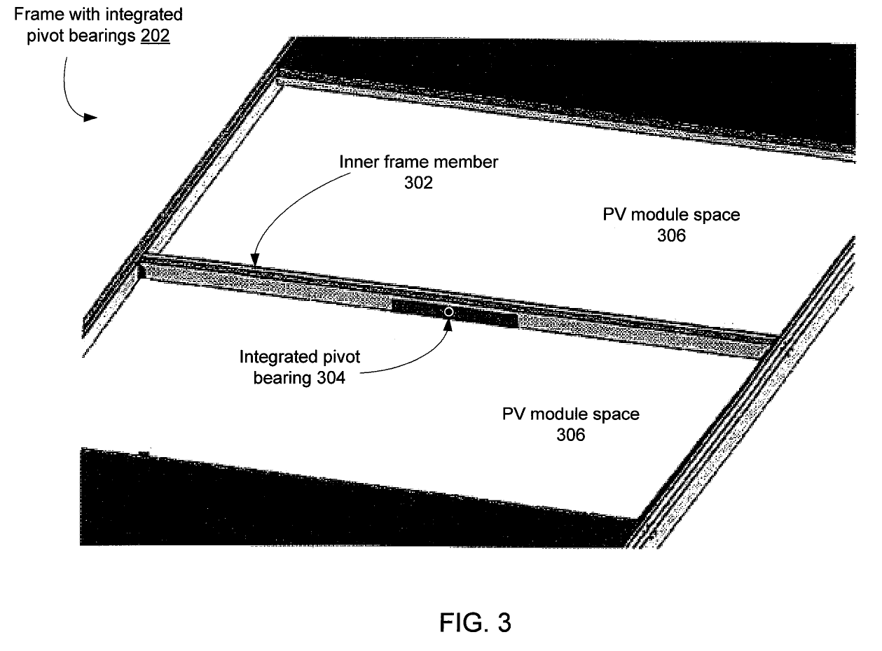

FIG. 3 depicts an integrated pivot bearing 304 in a frame 202 in accordance with an embodiment of the invention. As seen, the frame includes an inner frame member 302 which is in between two PV module spaces 306 and is not on an outer perimeter of the frame. In this embodiment, the integrated pivot bearing 304 is integrated into the inner frame member 302.

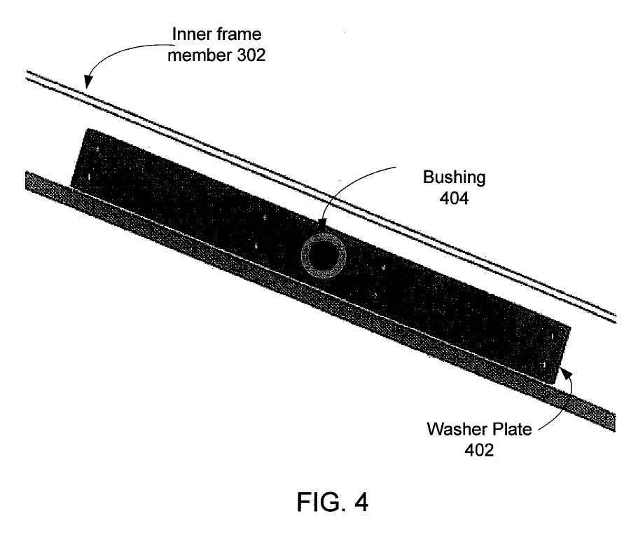

FIG. 4 depicts a closer view of the integrated pivot bearing in accordance with an embodiment of the invention. As shown, a washer plate 402 may be attached to the inner frame member 302, and a cylindrical flanged bushing 404 may be configured to fit within a hole in an inner frame member 302. The washer plate 402 may be made of metal and configured to reinforce the region of the inner frame member 302 that surrounds the hole for the bushing 404 and bears the weight of the array of PV modules. The washer plate 402 also serves to mechanically buffer between the bushing 404 and the inner frame member 302.

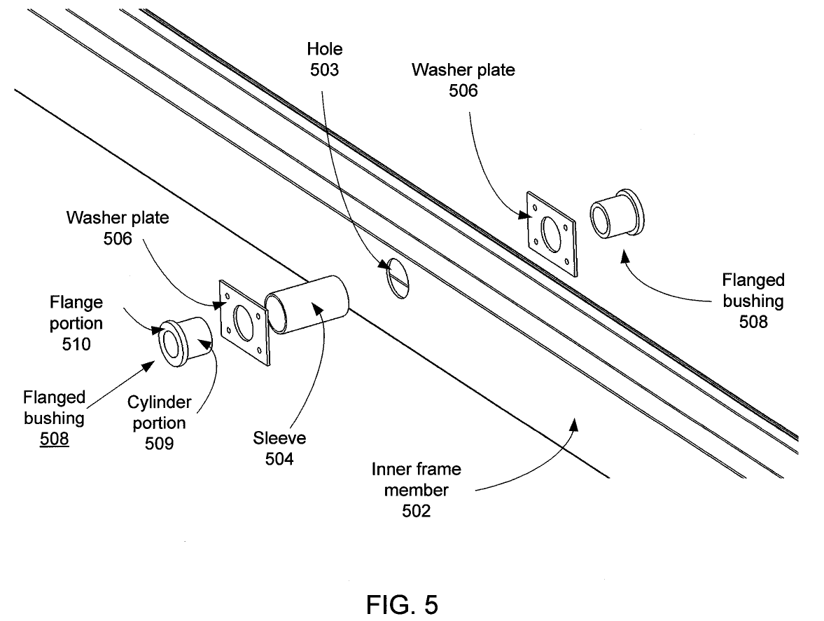

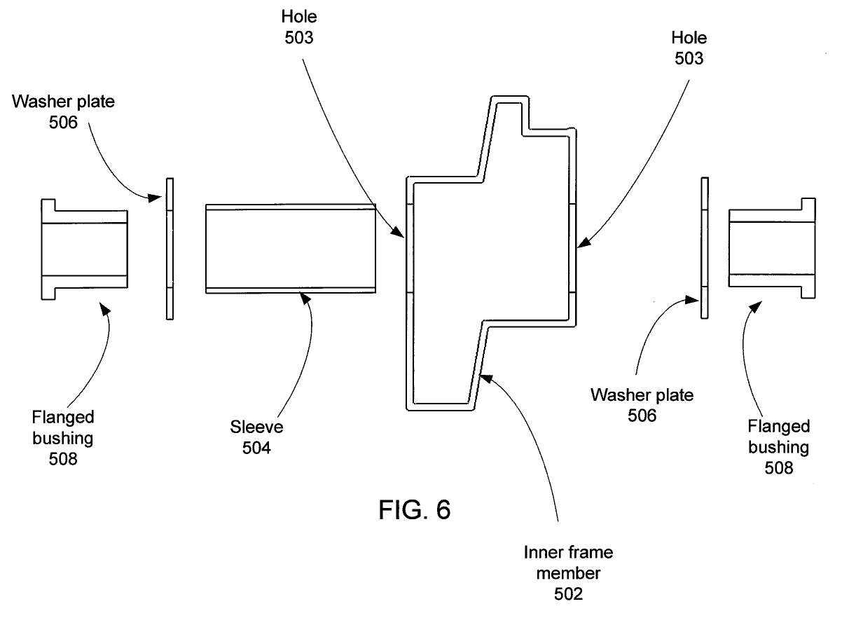

FIG. 5 is a perspective exploded view drawing and FIG. 6 is a cross-sectional view drawing, each showing separated parts of a frame-integrated pivot bearing in accordance with an embodiment of the invention. An inner frame member 502 is shown in these figures, the inner frame member 502 being positioned in between two PV module spaces and is not on an outer perimeter of the frame. As seen a hole 503 penetrates through the inner frame member 502, and a cylindrical sleeve 504 is configured to be positioned within the hole 503.

Washer plates 506 are configured to be attached to the inner frame member 502 on either side of the hole 503. Each of the washer plates 506 has a central plate hole 507. The central plate hole 507 preferably has a diameter equal to, or approximately equal to, the inner diameter of the cylindrical sleeve 504. As such, the washer plates 506 hold the sleeve 504 within the frame hole 503 when the central plate hole 507 is positioned concentrically with the frame hole 503. Note that the washer plates 506 in the embodiment shown in FIGS. 5-7 are similar in function, but smaller in length, compared with the washer plates 402 in the embodiment shown in FIGS. 3-4.

Flanged bushings 508 are configured with a cylindrical portion 509 to fit through the washer plate 506 and into the cylindrical sleeve 504 and a flanged portion 510 which fits against the washer plate 506. The cylindrical opening of the flanged bushings 508 are such that a pin of a pivot attachment may fit through the opening so as to attach the frame to piers 108 or other members of a support structure. In accordance with an embodiment of the invention, the flange bushings 508 may be used as a tracker pivot such that the array of PV modules may be rotated so as to track a diurnal motion of the sun.

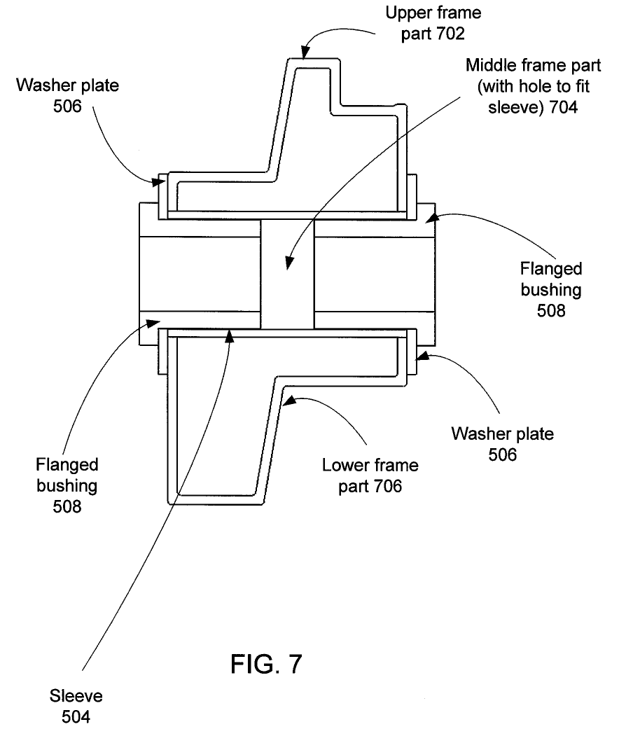

FIG. 7 is a cross-sectional view drawing showing an assembled frame-integrated pivot bearing in accordance with an embodiment of the invention. The inner frame member 502 is shown as an upper frame part 702, a middle frame part 704, and a lower frame part 706. The hole 503 to fit the sleeve 504 is configured in the middle frame part 704. The washer plate 506 is shown as attached to the inner frame member 502, and the flanged bushing 508 is shown as inserted into the sleeve 504 and positioned against the washer plate 506.

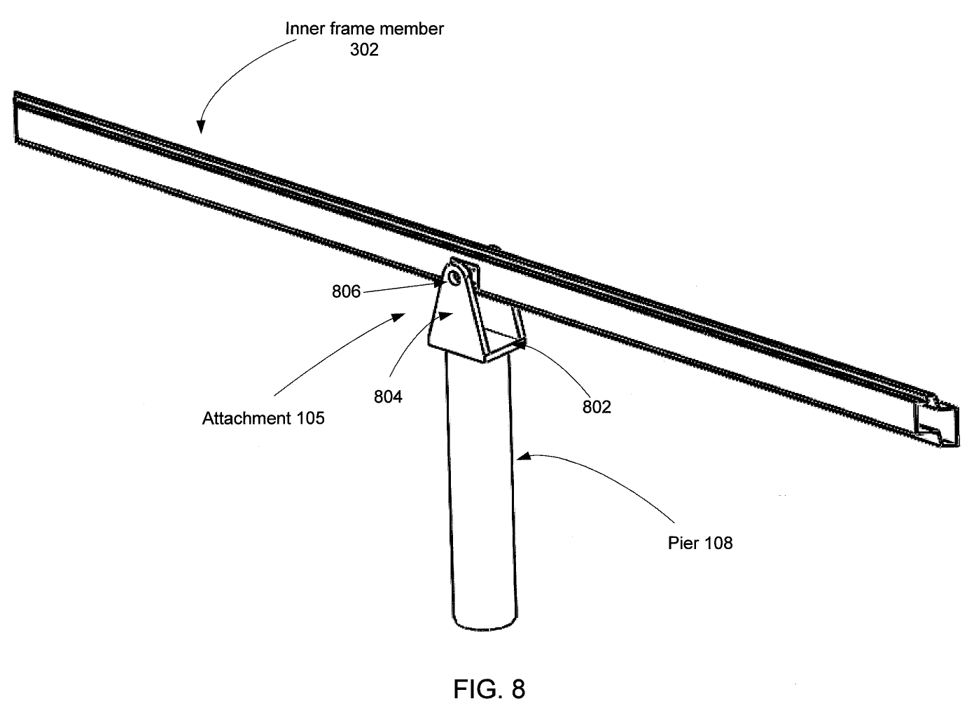

FIG. 8 is a perspective view of an attachment mechanism 105 between a pier 108 and an inner frame member 302 in accordance with an embodiment of the invention. As seen, in this embodiment, the attachment mechanism 105 may include a horizontal piece 802 attached to the pier 108 and two vertical pieces 804 connected to the horizontal piece 802.

In one implementation, each vertical piece 804 may include a hole 806. A rod may be inserted through the holes 806 and through the bushing 404. The rod may then be secured mechanically so that it remains in place. In this way, the inner frame member 302 may be movably attached to the pier 108.

In accordance with an embodiment of the invention, the frame-integrated bearings disclosed herein are advantageous in that loads from the bearing are transmitted directly to the frame holding the PV modules. The bearing retaining structure serves to reinforce the frame member such that a smaller frame cross section may be utilized, reducing overall material usage. Furthermore, the pivot bearings are advantageously located centrally near a neutral axis to minimize effects that the pivot hole has on the frame strength. A neutral axis may be defined as an axis in a cross section of a beam or shaft along which there are no longitudinal stresses or strains. In addition, the frame-integrated bearings ships in the frame itself and enables reduced effort for assembly of the tracking solar structure in the field.

Another embodiment of the invention relates to a method of manufacturing a photovoltaic array assembly. The method includes manufacturing a frame to surround and support a plurality of photovoltaic modules in an array. The method further includes integrating a plurality of pivot bearings into the frame and inserting the plurality of photovoltaic modules into the frame. The pivot bearings may be integrated into select members of the inner frame members so as to provide distributed support for the array. In accordance with one implementation, integrating a pivot bearing into each said select member comprises forming a hole in said select member, attaching a washer plate on each side of the hole, placing a sleeve within the hole, and inserting a cylinder portion of two flanged bushings through the opening and into the sleeve.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A photovoltaic array assembly comprising:
a plurality of photovoltaic modules;
a frame surrounding and supporting each of the photovoltaic modules in an array; and
a plurality of pivot bearings integrated into the frame along a single axis.

2. The photovoltaic array assembly of claim 1, further comprising a plurality of inner frame members configured so as to be between individual photovoltaic modules in the array, wherein the pivot bearings are integrated into select members of the inner frame members so as to provide distributed support for the array.

3. The photovoltaic array assembly of claim 1, wherein the pivot bearings comprise cylindrical sleeves.

4. The photovoltaic array assembly of claim 3, wherein the pivot bearings comprise flange bushings, each flange bushing having a cylindrical portion which is inserted into the cylindrical sleeves.

5. The photovoltaic array assembly of claim 4, wherein the cylindrical portion of each flange bushing has an inner diameter of no more than three inches.

6. The photovoltaic array assembly of claim 5, wherein the flange bushings are metal.

7. The photovoltaic array assembly of claim 5, wherein the flange bushings are plastic.

8. The photovoltaic array assembly of claim 4, further comprising washer plates attached to the inner frame member and arranged as a mechanical buffer between the inner frame member and the flange portion of the flange bushings.

9. The photovoltaic array assembly of claim 1, further comprising:
a plurality of piers for supporting the frame; and
an attachment mechanism on each pier, the attachment mechanism being configured to attach to the pivot bearings within the frame.

10. The photovoltaic array assembly of claim 1, wherein the attachment mechanism comprises a hole in each of two vertical members.

11. The photovoltaic array assembly of claim 10, wherein the attachment mechanism comprises a rod securely positioned through the holes of the vertical members and through a hole in the pivot bearing positioned.

12. The photovoltaic array assembly of claim 8, wherein the assembly is configured to be rotated axially about the single axis without use of a torque tube.

13. A method of manufacturing a photovoltaic array assembly, the method comprising:
manufacturing a frame to surround and support a plurality of photovoltaic modules in an array;
integrating a plurality of pivot bearings into the frame; and
inserting the plurality of photovoltaic modules into the frame.

14. The method of manufacturing of claim 3, wherein the frame comprises a plurality of inner frame members configured at positions so as to be in between individual photovoltaic modules in the array, and wherein the pivot bearings are integrated into select members of the inner frame members so as to provide distributed support for the array.

15. The method of manufacturing of claim 14, wherein integrating a pivot bearing into said select member comprises forming a hole in each said select member, attaching a washer plate on each side of the hole, placing a sleeve within the hole, and inserting a cylinder portion of two flanged bushings through the opening and into the sleeve.
